(19) United States
(12) Patent Application Publication
(10) Pub. No.: US 2003/0199153 A1
(43) Pub. Date: Oct. 23, 2003

(54) Method of producing SI-GE base semiconductor devices

(76) Inventors: Stephen J. Kovacic, Ottawa (CA); John N.M. Peirce, Ottawa (CA); John William Mitchell Rogers, Ottawa (CA); Nader Fayyaz, Ottawa (CA); David Rahn, Kanata (CA)

Correspondence Address: FREEDMAN & ASSOCIATES, 117 CENTREPOINTE DRIVE, SUITE 350, NEPEAN, ONTARIO, K2G 5X3, CA

(21) Appl. No.: 10/325,840

(22) Filed: Dec. 23, 2002

Related U.S. Application Data
(63) Continuation-in-part of application No. 09/988,938, filed on Feb. 1, 2002.
Application No. 09/988,938 is a division of application No. 09/492,463, filed on Jan. 27, 2000, now Pat. No. 6,346,453.
(63) Continuation-in-part of application No. 09/988,951, filed on Feb. 1, 2002, now Pat. No. 6,551,889.
Application No. 09/988,951 is a division of application No. 09/492,463, filed on Jan. 27, 2000, now Pat. No. 6,346,453.
(63) Continuation-in-part of application No. 10/096,899, filed on Mar. 14, 2002.
Application No. 10/096,899 is a continuation-in-part of application No. 09/534,083, filed on Mar. 24, 2000, now Pat. No. 6,433,611.
(63) Continuation-in-part of application No. 09/496,047, filed on Feb. 2, 2000, now Pat. No. 6,518,840.
(63) Continuation-in-part of application No. 09/858,544, filed on May 17, 2001.
(63) Continuation-in-part of application No. 09/870,792, filed on Jun. 1, 2001.
(63) Continuation-in-part of application No. 10/053,603, filed on Jan. 24, 2002.
(60) Provisional application No. 60/351,011, filed on Jan. 25, 2002.

(51) Int. Cl. C30B 1/00; H01L 21/36; H01L 21/20; C30B 19/00

(52) U.S. Cl. 438/479; 438/481; 438/489; 117/58

(57) ABSTRACT

Disclosed is a method of producing elementary semiconductor devices such as a field-effect transistor, a capacitor, a resistor, an inductor, a transformer, or a diode, and devices produced by said method. According to the method, a semiconductor seed layer is applied to a substrate having regions of exposed semiconductor material and regions of exposed dielectric material. The method comprises a step of disposing the substrate in a growth chamber and nucleating the seed layer by exposing the semiconductor material and dielectric material to an atmosphere of gases presented at a predetermined flow rate, temperature and pressure selected to provide contiguous growth of the seed layer, the seed layer growing in a single crystal lattice over predetermined windows within the mixed topology substrate.

This application is a continuation-in-part of (1) U.S. patent applications Ser. No. 09/988,938 filed Nov. 21, 2001 and Ser. No. 09/988,951 filed Feb. 1, 2002, which both are Divisionals of U.S. patent application Ser. No. 09/492,463 filed Jan. 27, 2000, now issued as U.S. Pat. No. 6,346,543 on Feb. 12, 2002; (2) U.S. patent application Ser. No. 10/096,899 filed Mar. 14, 2002, which itself is a continuation-in-part of U.S. patent application Ser. No. 09/534,083 filed Mar. 24, 2000, now issued as U.S. Pat. No. 6,433,611 on Aug. 13, 2002; of (3) U.S. patent application Ser. No. 09/496,047 filed Feb. 2, 2000; of (4) U.S. patent application Ser. No. 09/858,544 filed May 17, 2001; of (5) U.S. patent application Ser. No. 09/870,792 filed Jun. 1, 2001; of (6) U.S. patent application Ser. No. 10/053,603 filed Jan. 24, 2002; and of (7) U.S. Provisional Application No. 60/351,011 filed Jan. 25, 2002.

### FIELD OF THE INVENTION

The present invention relates generally to a method of producing a heterojunction bipolar semiconductor device, as well as to a method of producing a semiconductor device including a bipolar transistor having a SiGe base supported by an oppositely doped substrate, and relates in particular to a method for producing elementary semiconductor devices, such as a bipolar transistor, a field-effect transistor, a resistor, a capacitor, an inductor, or a diode.

### BACKGROUND OF THE INVENTION

To improve the operating speed of a bipolar transistor, it is important that the base layer be thin enough to minimize the time it takes electronic charges to move from the emitter to the collector, thereby minimizing the response time of the transistor, and have a high concentration of dopant in order to minimize base resistance. Typically, ion implantation technique is widely used to form a base layer. However, this technique has a problem of ion channeling, which limits the minimum thickness of the base layer to about 40 nm. Another disadvantage of ion implantation is that the Si/SiGe film is often damaged by the ions, and high temperature annealing is required which alters the concentration profile within the various layers of semiconductor material making up the transistor.

One known technique to avoid the above problem is to form a base layer using an epitaxial technique, which precisely defines the base region and inherently has no problem of channeling because the dopants are placed in the semiconductor layer during growth. With this technique, it is possible to form a base layer having a thickness smaller than 30 nm and having an arbitrary impurity concentration or profile by incorporating an impurity directly into the base layer during the epitaxial growth process. Using this technique, a high-speed bipolar transistor having a maximum cut-off frequency ƒ_{T} as high as 200 GHz has been realized.

Although the bipolar transistor fabricated with the above technique has such a high maximum cut-off frequency ƒ_{T} as a result of the thin base, the engineering trade-off is high base resistance (R_{b}), which may limit the maximum frequency of oscillation fₘₐₓ to 30-40 GHz.

To further increase the impurity concentration of the base layer to reduce the base resistance (R_{b}), it is required to increase not only the impurity concentration of the base layer but also that of the emitter layer so that a sufficiently high current gain (hFE) can be obtained.

However, the further increase in the impurity concentration of the emitter can cause a reduction in bandgap which in turn results in a reduction in the injection efficiency, a reduction in the emitter-base breakdown voltage, and an increase in the emitter-base junction charging time constant τ_{EB}. Since the requirements among these parameters conflict with each other, there is a limitation in the improvement in the operating speed.

Notwithstanding, this conflict can be avoided by employing a heterojunction between the emitter and base in which the bandgap of the emitter is different from that of the base. For example, silicon germanium (SiGe) having a narrower bandgap than silicon is used as a base material so as to form a practical heterojunction. In the heterojunction structure, the emitter can inject charge carriers with greater efficiency into the base than the emitter of the homogeneous junction structure. This makes it possible to achieve a sufficiently high current gain without increasing either the base resistance (R_{b}) or the emitter-base junction charging time constant τ_{EB}, and thus it is possible to realize a high-speed bipolar transistor having a maximum frequency of oscillation fₘₐₓ as high as about 200 GHz.

To fabricate a heterojunction bipolar transistor, it is important to control the distributions of p-type impurity and germanium (Ge) across the base layer so that the Ge profile is formed at a precise location with respect to the p-n junction. As was stated earlier, transistor performance is greatly affected by the incorporation of Ge and the concentration profiles of the dopants. Moreover, the interaction of bandgap profile with the dopant profile is also an important factor in the overall design of the transistor and the performance. If the location of the Ge profile—that is, the concentration of Ge versus position with respect to the dopant position is not controlled precisely from wafer to wafer, or from manufacturing lot to manufacturing lot, or even across the wafer, then transistor performance will vary accordingly. In one area of the wafer, for example, transistors with excellent high-frequency response may be realized while at a different location, poor high-frequency response might be seen. Correspondingly, these differences in transistor performance may result in poor circuit yield, and increased circuit testing costs.

With reference to FIGS. 1A-1C, a conventional method of producing a junction bipolar transistor is described below. As shown in FIG. 1A, an n⁺ buried collector layer 112 is formed on the surface of a silicon substrate 111 by means of solid-state diffusion or ion-implantation. An epitaxial layer 113 with an impurity concentration of 5×10¹⁶ atoms/cm³ is then epitaxially grown thereon by means of an epitaxial growth technique. The epitaxial layer 113 is locally oxidized (for example by the LOCOS (local oxidation of silicon) method so as to form a device isolation oxide film 114. The surfaces of the epitaxial layer 113 and the device isolation oxide film 114 can be planarized. In addition, an ion implantation process is then performed either before oxidation or after so that a p⁺ device isolation diffusion layer 115 is formed under the device isolation oxide film 114. Another ion implantation process is performed to form an n⁺ collector contact diffusion layer 116 connected to the n⁺ buried collector layer 112.

Then as shown in FIG. 1B, a 30 nm thick silicon germanium (Si_{0.8} Ge_{0.2}) film containing boron (B) acting as a p-type impurity with a concentration of about 3×10¹⁹ atoms/cm³ is formed over the entire surface area of the epitaxial layer 113. A 50 to 80 nm thick silicon film containing an n-type impurity with a concentration of about 3×10¹⁸ atoms/cm³ is then formed thereon.

Ion implantation and activation annealing are then performed so as to dope the surface region of the emitter layer 118 with an n-type impurity to a high concentration (for example in the range from 1×10²⁰ atoms/cm³ to the solid solubility level) thereby forming an emitter contact layer 119. The activation annealing should be performed in the range from about 850° C. to 900° C. A base and an emitter on the base are then formed by means of a patterning technique.

Subsequently, as shown in FIG. 1C, an interlayer insulating film 121 is formed and then contact holes 122, 123, and 124 are formed in the interlayer insulating film 121. Electrodes 125, 126, and 127 are then formed such that these electrodes are in contact with the base layer 117, the emitter contact layer 119, and the collector contact diffusion layer 116, respectively, through the contact holes 122, 123, and 124.

In another (second) conventional technique, the base layer, the emitter layer, and the emitter contact layer are formed by means of a low-temperature epitaxial growth process. In a still another (third) conventional technique, after epitaxially forming the base layer and the emitter layer, an n-type impurity region is formed by means of an ion implantation process.

In the first conventional technique, however, if the base layer is subjected to a heat treatment at a temperature higher than approximately 800° C., diffusion of boron (B) and germanium (Ge) in the base layer occurs. If such a diffusion occurs, the base width will be expanded and discrepancy in position between the bandgap profile and the p-n junction will occur. Furthermore, since the base layer of silicon germanium (SiGe) has a thickness greater than the critical film thickness determined by the thermal equilibrium theory, the high-temperature heat treatment will introduce dislocations, which will result in a degradation in transistor performance.

As shown in FIG. 2, immediately after the formation of the base layer by means of the epitaxial growth technique, it has a boron concentration distribution limited within a narrow range represented by a broken line, which is coincident with the range of the silicon germanium mixed crystal. However, boron atoms (B) diffuse during heat treatment performed after the formation of the base layer. As a result, the boron distribution is spread as represented by a solid line. Thus, the heat treatment causes an increase in the base width, which makes it difficult to achieve a high-speed operation. In FIG. 2, the vertical axis represents the impurity concentration, and the horizontal axis represents the depth across the emitter, the base, and the collector.

In the second example of the conventional technique described above, when the epitaxial growth is performed at a low temperature below 800° C., the surface of silicon becomes chemically more inactive due to adsorption of group V elements with the increase in the concentration of n-type impurity contained in the [ambient] in which the epitaxial growth is performed. This leads to a great reduction in the growth rate to a level, which is too low for practical production.

On the other hand, in the third conventional technique, heat treatment at a rather high temperature is required to activate the implanted ions and to remove damage induced in the crystal during the ion implantation process. During the crystal annealing process, interstitial silicon atoms are generated, which can result in an increase in the diffusivity of boron (B) by two or more orders of magnitude.

The generation of interstitial silicon atoms in the ion implantation process is also a problem when an emitter is formed of polysilicon. If in-situ doped polysilicon is employed, the problem of enhanced diffusion of boron (B) due to the generation of interstitial silicon can be avoided. However, it is difficult to grow polysilicon on silicon without having a native oxide layer at the interface between the silicon and the polysilicon. The formation of the native oxide results in an increase in the emitter resistance.

Furthermore, when a bipolar transistor having a shallow base layer is formed together with another type of device such as a metal-oxide-semiconductor (MOS) transistor on the same substrate if polysilicon is employed to form the gate electrode of the MOS transistor, and the emitter, base and collector electrodes of the bipolar transistor as well as a resistor element, the polysilicon is required to be doped with an impurity to a high enough concentration, and the impurity atoms have to be activated by high-temperature heat treatment.

However, the impurities incorporated into the Si and SiGe films can diffuse during the high-temperature heat treatment. Thus, even if the above thin films are formed by means of the epitaxial technique, the high-temperature heat treatment leads to changes in the impurity profiles. Thus the effective thicknesses of the films become different from their original thickness.

When a SiGe film is employed as the base layer, since the lattice constant of Ge is 4% greater than that of Si, an internal stress occurs at the interface between the Si substrate and the SiGe film formed on the Si substrate. Therefore, if heat treatment is performed after forming the SiGe film on the Si substrate, a plastic strain occurs in the SiGe film so that the above internal stress is relaxed. As a result, lattice defects are created in the SiGe film. Since the above internal stress increases with increasing the Ge content, the sensitivity to the heat treatment decreases with the increasing Ge content.

On the other hand, the bandgap decreases with the increasing Ge content and having the alloy under stress with respect to the underlying silicon. It is advantageous to preserve the stress in the film and incorporate the proper amount of Ge into the alloy in order to create the correct heterojunction.

As can be understood from the above discussion, the advantages of the shallow base layer (of SiGe or Si) formed by means of the epitaxial technique are lost by the heat treatment performed on the substrate after the formation of the shallow base layer.

It is therefore an object of the instant invention to provide a method for producing semiconductor devices, and to provide semiconductor devices produced by said method, the method overcoming most of the limitations of prior processes for fabrication of said devices, having particular physical properties.

### SUMMARY OF THE INVENTION

In accordance with an aspect of the instant invention, there is presented a method of applying a semiconductor seed layer to a substrate having regions of exposed semiconductor material and regions of exposed dielectric material. The method comprises the step of disposing the substrate in a growth chamber and nucleating the seed layer by exposing the semiconductor material and dielectric material to an atmosphere of gases presented at a predetermined flow rate, temperature and pressure selected to provide contiguous growth of the seed layer, the seed layer growing in a single crystal lattice over predetermined windows within the mixed topology substrate.

In accordance with another aspect of the instant invention, there is presented a method of applying a semiconductor seed layer, the seed layer essentially consisting of a silicon layer containing impurities, to a mixed topology substrate having regions of exposed semiconductor material and regions of exposed dielectric material, the method comprising the step of disposing the substrate in a growth chamber and nucleating the seed layer by exposing the semiconductor material and dielectric material to an atmosphere of gases presented at a predetermined flow rate, temperature and pressure selected to provide contiguous growth of the seed layer, the seed layer growing in a single crystal lattice over predetermined windows within the mixed topology substrate.

In accordance with yet another aspect of the instant invention, there is presented a semiconductor device comprising a silicon layer of a first conductivity type, a layer of SiGe of a second conductivity type covering at least a region of the silicon layer, a first layer of polysilicon of the second conductivity type at least substantially supported by and covering a portion of the SiGe layer, and an electronic component formed within the semiconductor device.

### BRIEF DESCRIPTION OF THE DRAWINGS

Exemplary embodiments of the invention will now be described in conjunction with the drawings in which:

FIGS. 1A-1C is a schematic representation of the processing steps of producing a semiconductor device according to a conventional technique;

FIG. 2 is a graph illustrating an impurity profile;

FIGS. 3 through 13 are cross-sectional views of schematic representations of a structure illustrating various process to produce a “double poly” SiGe heterojunction bipolar transistor (HBT) in accordance with this invention;

More particularly, FIG. 3 illustrates a portion of a pre-treated silicon wafer in condition to accept a layer of SiGe and a layer of Si in a region for forming a transistor;

FIGS. 3A and 3B illustrate the process of depositing a nucleation layer in accordance with an aspect of this invention;

FIG. 4 is an illustration showing a layer of SiGe and Si supported by the substrate;

FIG. 5 is a more detailed view of the region of interest wherein portions of the SiGe/Si shown in FIG. 4 have been etched away;

FIG. 6 is a detailed view of a mesa that has been created overtop of the SiGe/Si layers;

FIG. 7 is a detailed illustration of the mesa shown in FIG. 6, wherein a layer of oxide is deposited thereon;

FIG. 8 is a detailed side view of as shown in FIG. 7 wherein a layer of polycrystalline silicon has been deposited and after the upper surface is polished to a planar surface;

FIG. 9 is an illustration of uppers layers of the device after the polycrystalline silicon has been oxidized and the mesa has been removed by etching;

FIG. 10 is an illustration of the layers after the mesa has been removed;

FIGS. 11 through 13 illustrate the completion steps required to form an active device;

FIGS. 14 through 24 illustrate views of a transistor in various states of manufacture, to its completion.

FIG. 25 is a schematic diagram of a two-stage amplifying circuit manufactured by a method according to the instant invention;

FIG. 26 is a is a schematic diagram of a voltage level shift circuit manufactured by a method according to the instant invention;

FIG. 27 is a is a schematic diagram showing a load circuit manufactured by a method according to the instant invention, the load circuit for use with a voltage level shift circuit;

FIG. 28 is a detailed schematic diagram of an example of a radio frequency amplifier and an active impedance notch filter manufactured by a method according to the instant invention;

FIG. 29 is a block schematic diagram of a frequency modulation (FM) transceiver, built from semiconductor devices manufactured by a method according to the instant invention;

FIG. 30 is a schematic block diagram illustrating an example of a television receiver manufactured by a method according to the instant invention; and

FIG. 31 is a schematic block diagram of an integrated television tuner having band-pass filters, manufactured by a method according to the instant invention.

### DETAILED DESCRIPTION OF THE INVENTION

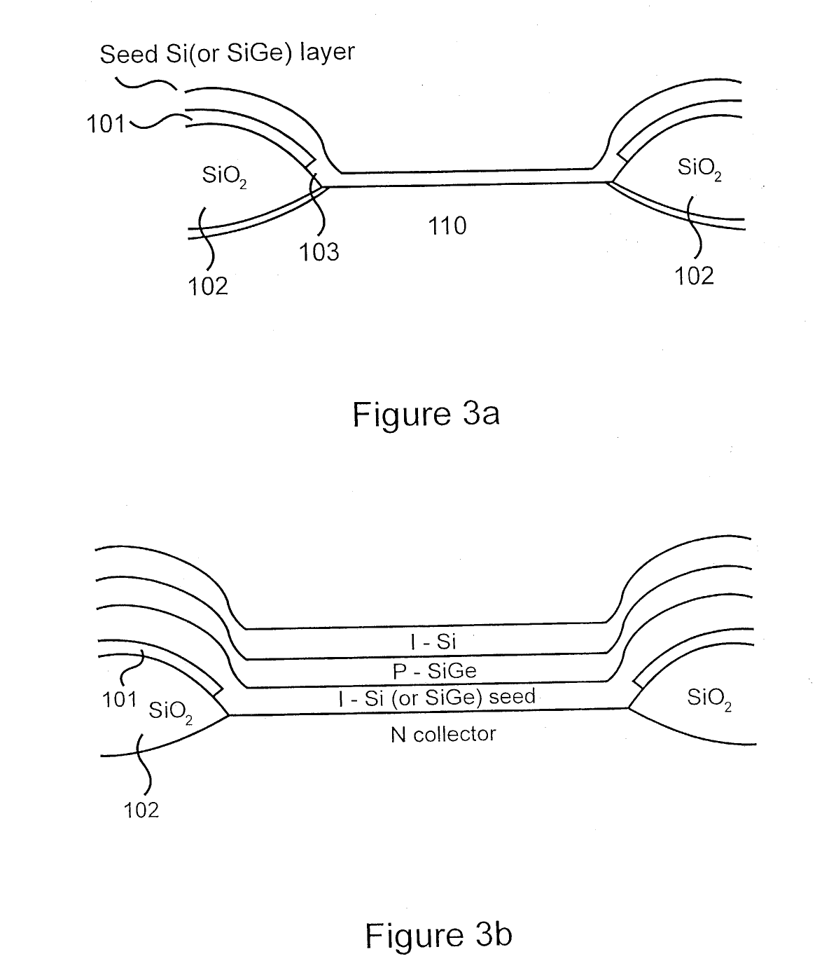

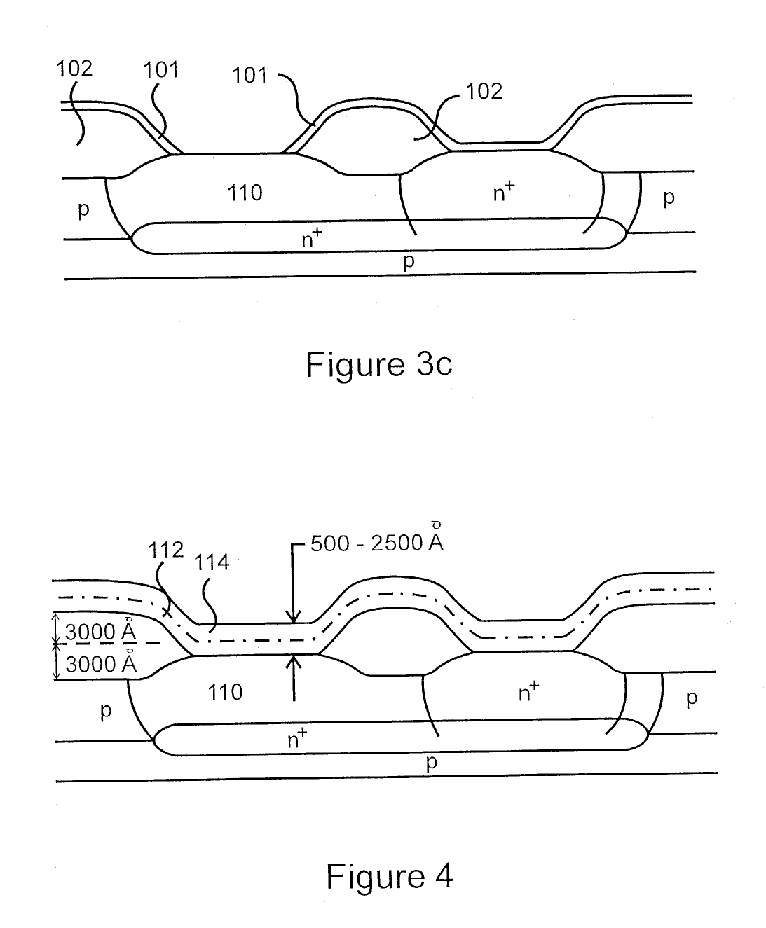

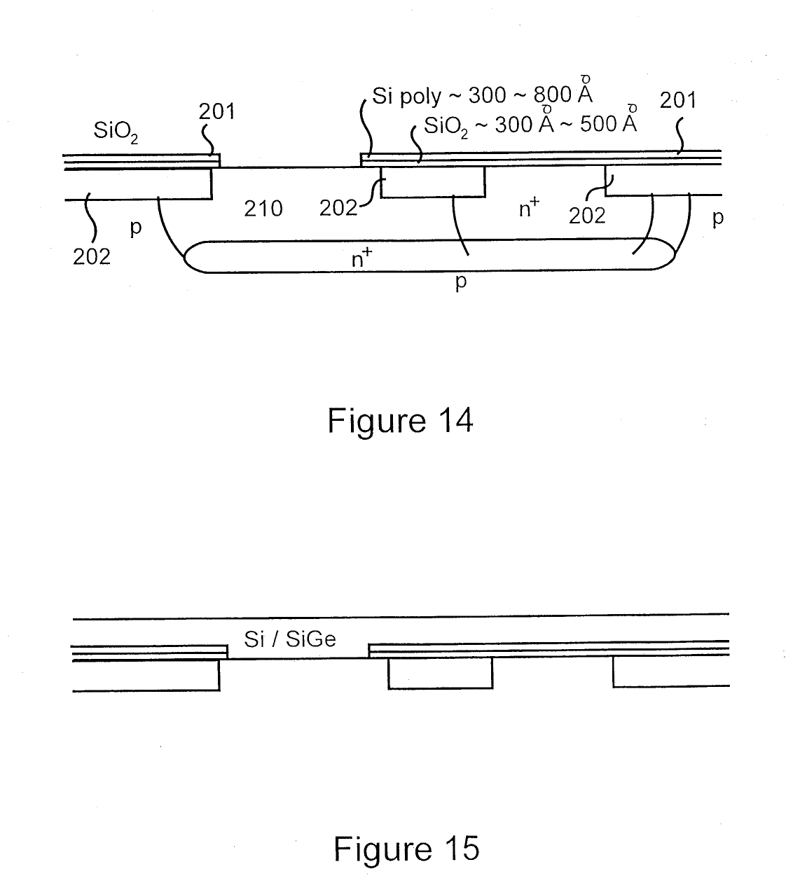

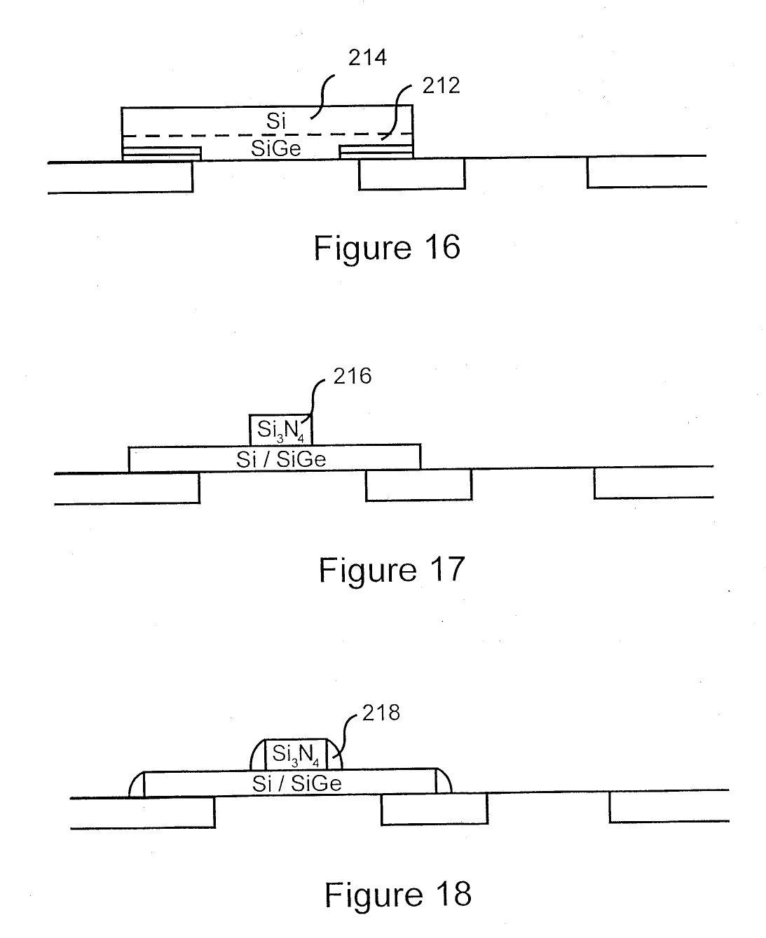

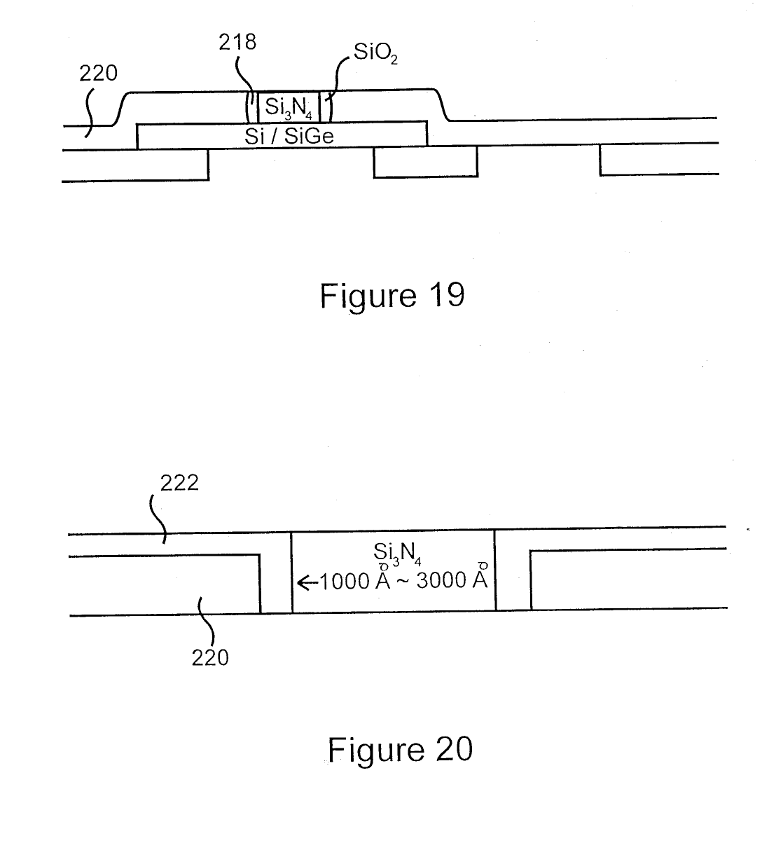

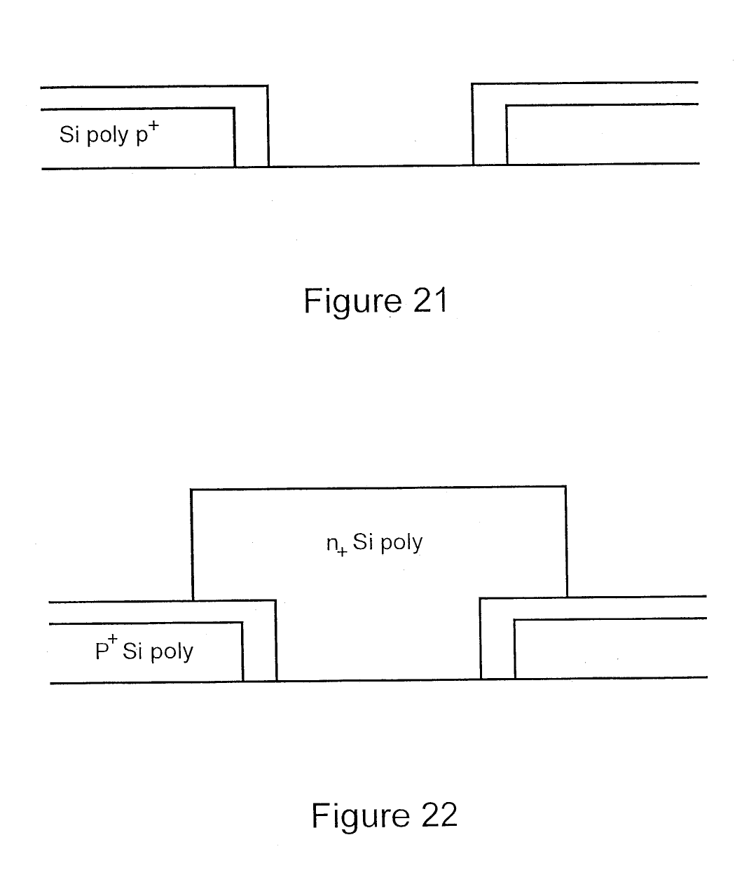

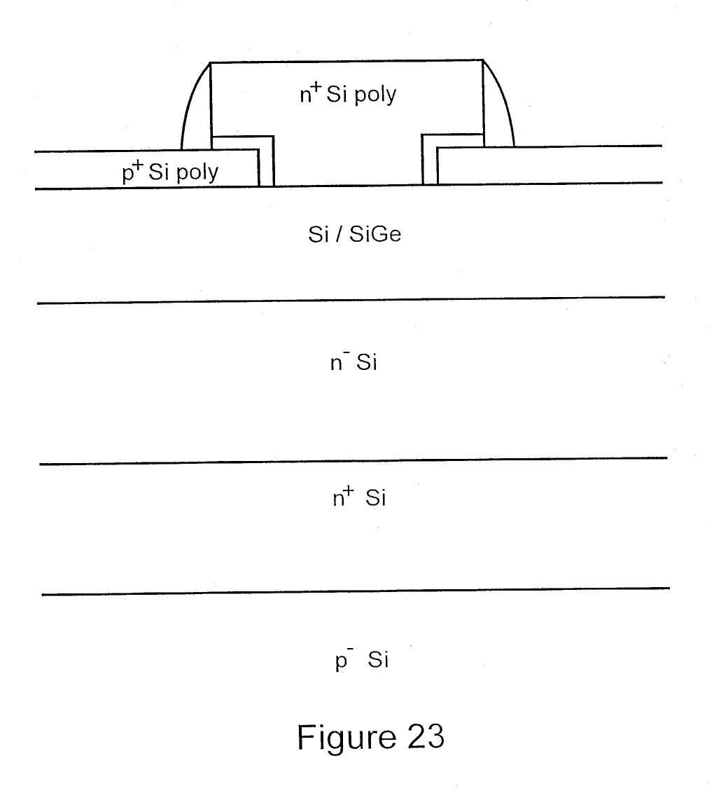

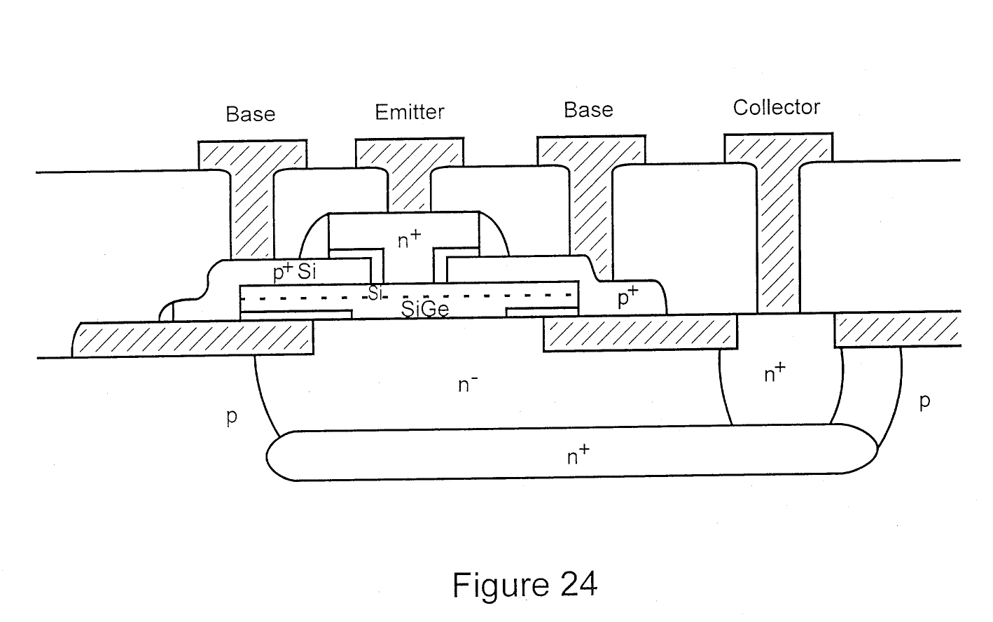

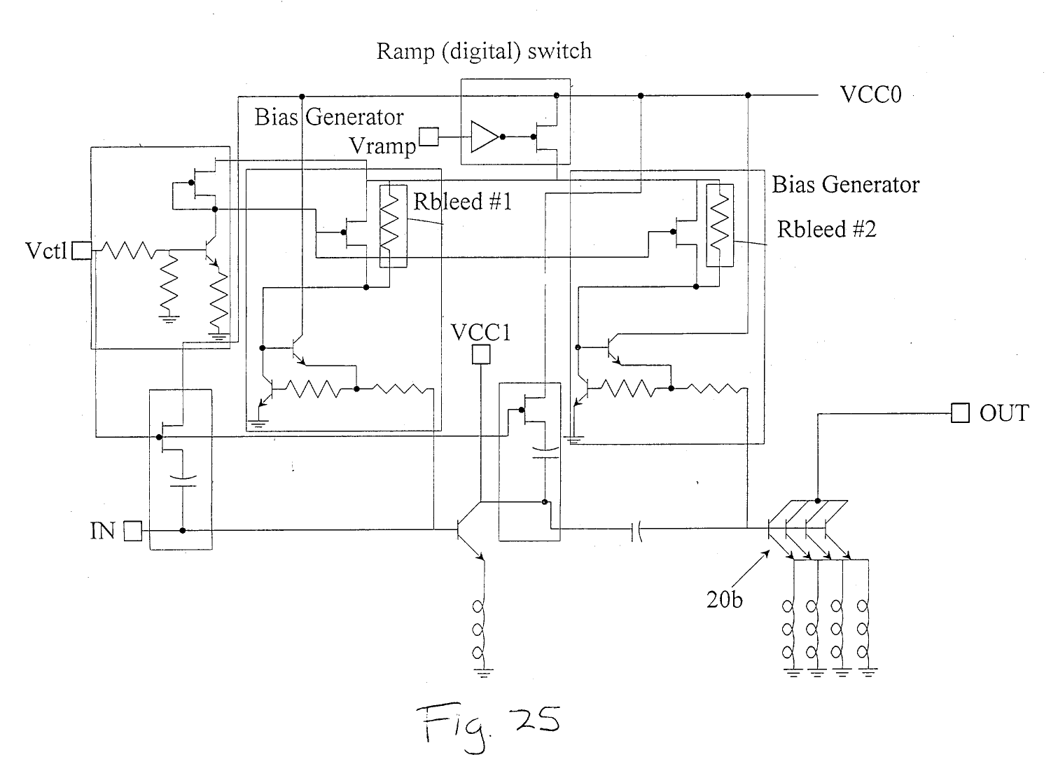

FIGS. 3 through 13 illustrate sequential steps in the formation of a bipolar junction transistor starting with a silicon wafer. FIGS. 14 through 24 illustrate same sequential steps for the formation of a BJT wherein the layers formed are planar.

FIG. 3 a silicon wafer is shown, serving as both a substrate 110 and collector of a bipolar junction transistor. The silicon substrate 110 has a region of n⁺-doped material buried within the substrate providing as a low resistance sub-collector. The following process steps will illustrate the formation of a base and emitter, wherein the base of the transistor is grown over a region of the substrate 110. Regions 102 of field oxide SiO₂ are disposed over the silicon, providing insulating regions. A thin 100-800 Å layer 101 of poly-silicon is deposited over a portion of the field oxide regions 102 and over a small region of the window of silicon 110 between the two field oxide regions 102 shown, which serve as a sacrificial material to minimize loading effects and which minimize the effect of moisture within SiO₂ regions 102. The thin poly-silicon layer 101 also provides a surface upon which a layer of SiGe will adhere, and forms an electrical contact to the SiGe layer.

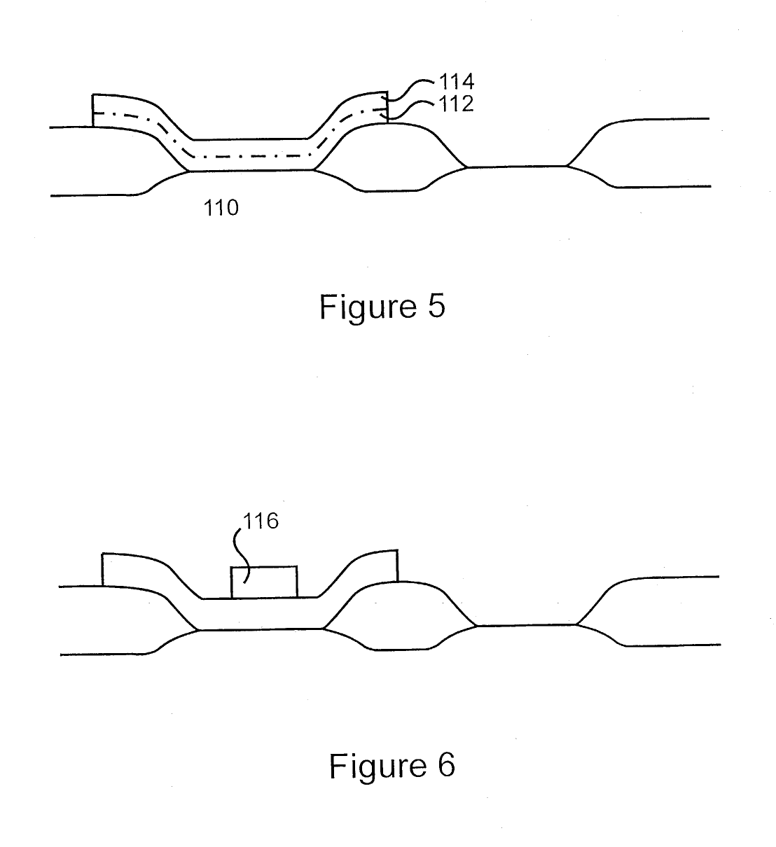

Turning now to FIG. 4, a layer 112 of p-type SiGe is first deposited over the n-type silicon substrate 110 and a layer 114 of intrinsic Si is grown over the SiGe layer 112. The SiGe layer 112 is pre-doped and is not implanted with p-type ions after it is deposited over the substrate. The layers 112 and 114 form the base and emitter-seat of the transistor, respectively, and have a combined thickness between 500 and 2500 Å. It is preferred that the layer 112 of SiGe grown over the silicon substrate 110 be uniform over a “window” of interest between the field oxide regions 102, that will form the p-type base of the BJT. FIG. 5 illustrates the surface after unwanted SiGe/Si material in particular regions is etched away leaving SiGe and Si only in desired location. A layer of a suitable material such as SiOₓN_{y}, more specifically SiO₂ or preferably Si₃N₄, for forming an etchable mesa 116 is subsequently deposited over top of SiGe/Si resultant layers 112 and 114 to form a mesa or pedestal, that will itself later be etched away without etching the underlying SiGe/Si layers 112 and 114, as illustrated in FIG. 6. It is important that the SiGe/Si layers 112 and 114 not be inadvertently etched since the p-type dopant is already positioned within the layer 112 grown on the silicon substrate 110; this is in contrast to prior art techniques where an ion implanter is used to dope the base region of the transistor with p-type dopant. Thus, if some of the SiGe/Si layers were inadvertently etched, the overall thickness and/or the uniformity of the thickness of the SiGe layer will be varied, altering the transistor's electrical characteristics. Of course it is desired to have uniformity across the transistor base layer. It is required that the mesa is composed of a material, which can be etched selectively from the underlying SiGe/Si and the oxide sidewalls. Reactive ion etching may also be required after depositing the mesa 116 in order to confine it to a region of a desired size to temporarily mask an emitter window. Although the maximum height of this mesa is not restricted, it is preferable to be approximately 2000 Å or of a height that is at least coincident of a thickness of a layer of Si-poly that will subsequently be deposited adjacent thereto.

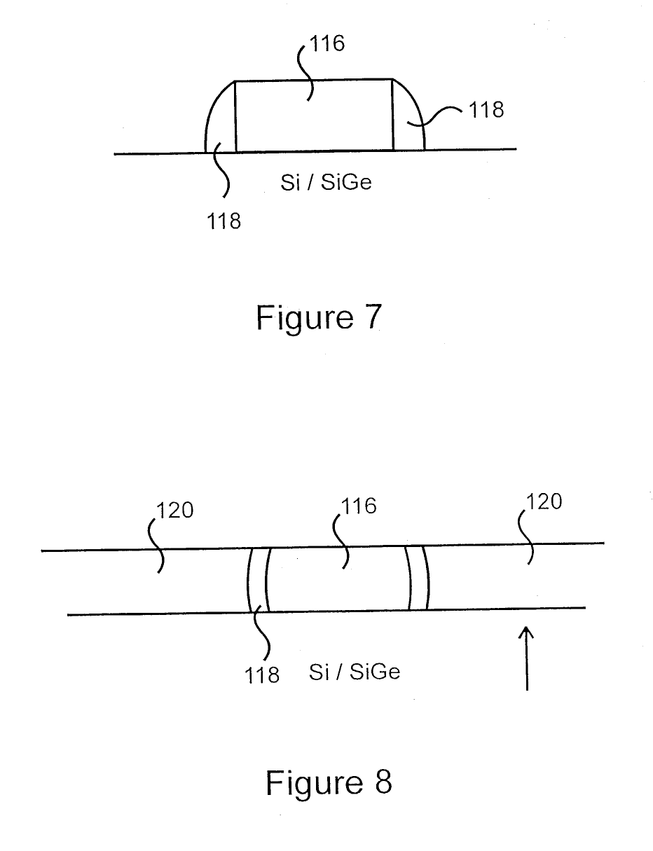

In FIG. 7 an oxide 118 of SiO₂ is shown placed on the sidewalls of the Si₃N₄ mesa 116 having a thickness at its base in the range of 1000-3000 Å, which serves as an insulating layer. In the following process step, depicted in FIG. 8, a layer 120 of p⁺ silicon poly (polycrystalline silicon) is deposited entirely over the Si₃N₄ mesa 116 and the SiO₂ sidewall oxide 118. FIG. 8 illustrates the layer structure after etching back preferably by polishing to a thickness of approximately 500 Å and to provide a planar surface.

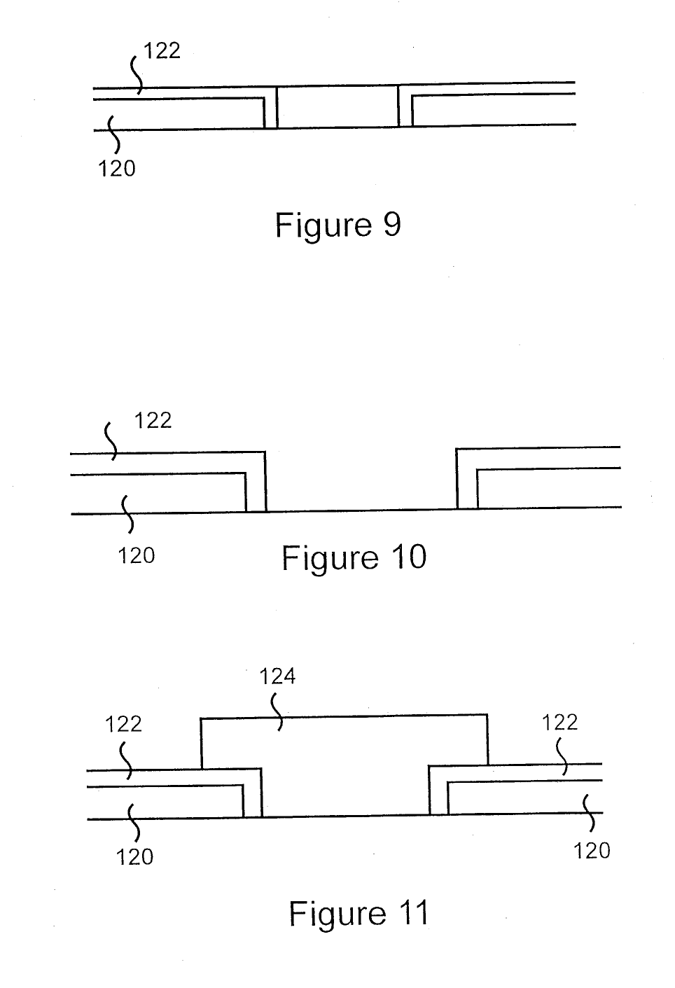

FIGS. 9 and 10 illustrate two subsequent process steps, whereby a SiO₂ layer 122 is formed over the layer 120 of p⁺ polycrystalline silicon followed by the removal of the Si₃N₄ mesa 116 to expose the window of SiGe/Si. Of course it is necessary to ensure the layers 112 and 114 of SiGe/Si below the mesa 116 are not etched as their thickness should be uniform and preserved so that its electrical characteristics are not changed.

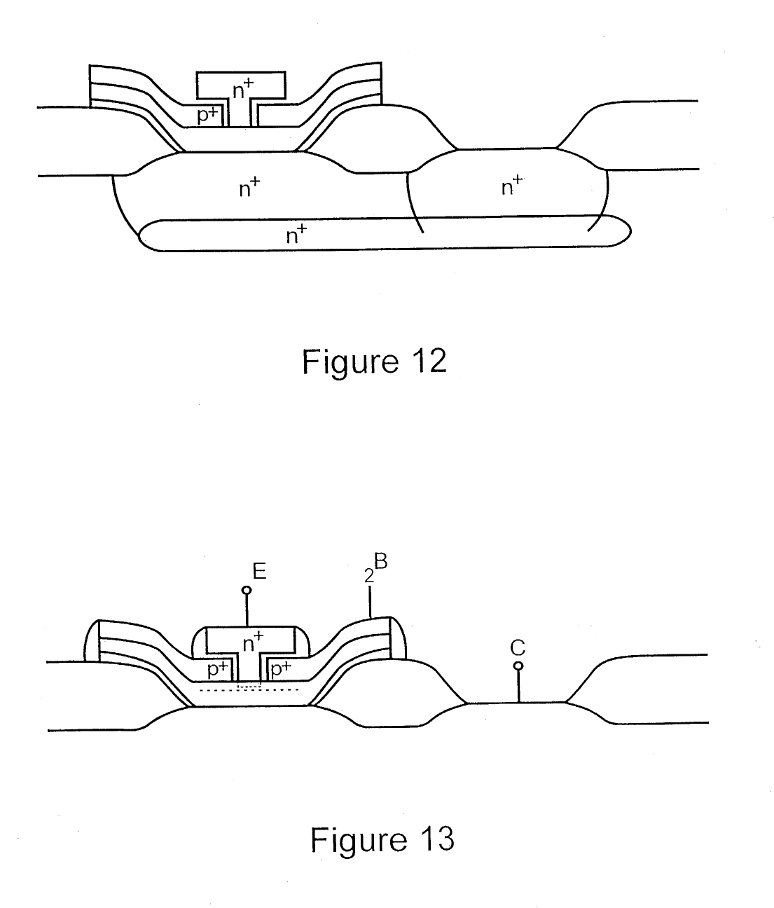

In FIG. 11 the window is filled with a poly Si layer 124 which can be doped during deposition or ion-implanted to make it n-type. This layer forms the emitter of the transistor. Later, in the presence of a suitable amount of heat, some of the n-type dopant in the emitter diffuses in to the Si/SiGe layers 112 and 114 to form an n-type region near the p-type SiGe base. This is the emitter-base junction and, of course, it is positioned accordingly with respect to the Ge profile. The combination of the proper p-n junction with the changing energy bandgap provides a suitable heterojunction. Referring to FIG. 12 and FIG. 13, an oxide is deposited on the sidewalls to create sidewalls, which further isolate n-type and p-type poly areas.

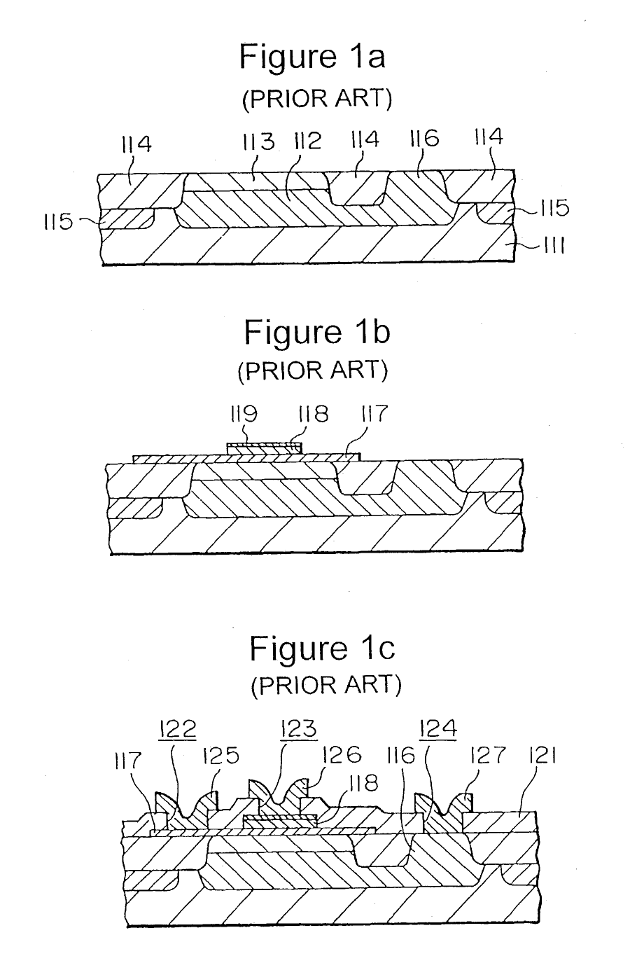

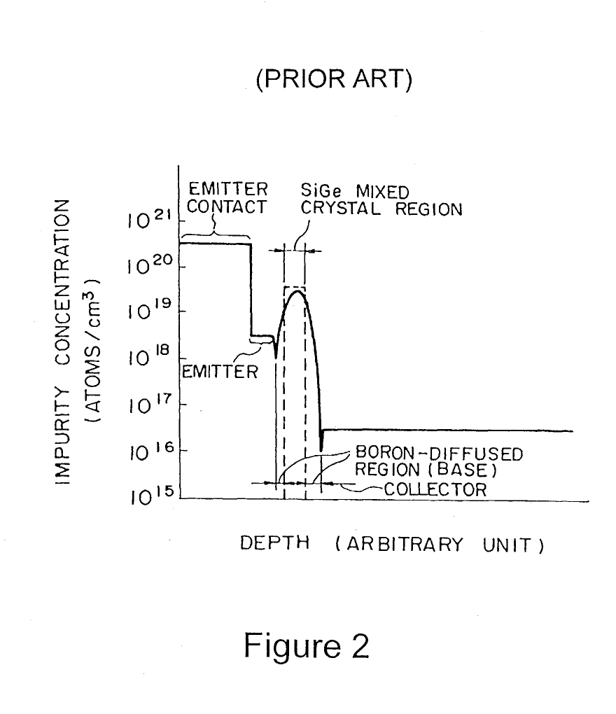

Turning now to FIGS. 14 through 24, substantially same process steps are employed in the manufacture of a BJT having a more planar topology. Elements 201, 202, 210, 212, 214, 216, 218, 220, 222 and 224 are shown which are similar to elements 101, 102, 110, 112, 114, 116, 118, 120, 122 and 124, respectively, in FIGS. 1 through 13.

An essential step in a manufacturable epitaxial process is the reproducible deposition of epitaxial silicon and/or SiGe on a mixed topography, i.e. single crystal silicon, poly Si, and oxide (or nitride) of variable roughness. This invention discloses a method for deposition of a seed layer atop the collector region to form a planar surface and a thin uniform thickness, continuous interconnecting silicon or silicon germanium layer without pinholes and defect free. Turning now to FIGS. 3A and 3B a preferred embodiment of the invention is shown wherein a nucleation seed layer of Si or SiGe is applied over a mixed topology of layers shown, comprising poly-silicon 101, a section 103 of the region 102 of SiO₂, and the silicon substrate 110. This is accomplished at ultra low pressure and ultra-low flow rates to provide adequate time for nucleation of the deposited layer on all surfaces; oxide, nitride, polysilicon, epitaxial silicon and SiGe. Smooth deposited layers of uniform thickness with continuous coverage of all surfaces are possible using this method. In order to have the continuous film or seed layer deposit and nucleate over the entire region of the dissimilar materials such as dielectric material and semiconductor material, it is important to meet several conditions. Deposition is preferably performed at a low temperature below 600° C., a low pressure of less than 10⁻² mbar, and at low flow rate of less than 5 cm³/min. Another advantage to this method, is that in a mixed topography wherein relatively different sized Si and oxide regions exist, by depositing a seed layer in accordance with the teachings of this invention over top of these regions, at low temperature, pressure and flow rate, loading effects are substantially minimized when the SiGe layer is deposited upon the seed layer. Seed layers have been discussed in the prior art, however these layers have not achieved a desired effect of nucleating a continuous film over a large region of dissimilar materials including dielectrics and semiconductors. Furthermore, prior art seed layers are applied at higher temperatures, flow rates and pressure than are taught in this invention in order to increase the throughput. Surprisingly, the inventors discovered that lowering the temperature, pressure and flow rate allowed nucleation that would not otherwise occur. Without the seed layer no deposition on oxide or nitride surfaces is possible thereby resulting in a discontinuous film of silicon or SiGe over mixed surface topography, which would substantially increase R_{b}. Planarization of the prior surfaces, reduces roughness and removes prior process deficiencies. Residual patches of silicon dioxide or carbon-containing material on the exposed silicon window surface can result in defects during post epitaxy processing by injecting dislocations and other defects such as stacking faults. The seed layer drastically reduces this tendency by introducing a planar surface coverage thereby removing the stress concentration at any heterogeneity in the interface and at discontinuities in the surface, for example silicon/silicon dioxide/poly silicon.

The method of providing the seed layer will now be described in accordance with a preferred embodiment of the invention. Prior to introduction into the UHVCVD system all surfaces of the wafer are cleaned using standard RCA cleaning procedures and dipped to hydrophobicity in a 10:1 diluted HF/H₂O to ensure removal of contamination debris from processing and residual native oxide from silicon rich surfaces. Immediately on insertion of the wafers into the growth chamber under a flow of preferably less than 500 sccm of hydrogen, silane at the reduced flow rate of less than 20 sccm is injected into the deposition chamber to initiate the nucleation of silicon and produce the seed layer on all exposed surfaces. The seed layer has a thickness for conformal nucleation of Si from silane. Preferably, the thickness of the “nucleation layer” is a minimum of 2 nm and is optimized for a specific mixed topography in the range of 2 to 20 nm is optionally doped with impurities such as B or P, p- or n-type.

Methods for producing SiGe based semiconductor devices have been described in reference to a bipolar transistor. A person of skill in the art will appreciate that the methods described above also apply to the production of other semiconductor devices, and to the production of integrated circuits. The semiconductor devices are elementary semiconductor devices such as a field-effect transistor, a capacitor, a resistor, an inductor, a transformer, or a diode. Further, the semiconductor devices possibly comprise semiconductor building blocks, formed by more than one elementary semiconductor device, such as an amplifier, an adder, a mixer, a filter, an oscillator, a tank circuit, a frequency conversion circuit, an analog-to-digital converter circuit, a bias control circuit, a gain control circuit, or a synthesizer. In the following, examples will be presented illustrating devices and circuits manufactured according to the methods described above.

The methods according to the instant invention are for example used in manufacturing a circuit for linearizing a power control profile of a bipolar complementary metal-oxide-semiconductor power (BiCMOS) amplifier. Turning now to FIG. 25, a circuit is shown having a first pre-amplifying transistor 20a, followed by a power amplifying transistor 20b coupled through a capacitor 22 for allowing an AC signal to pass to the base of the transistor 20b. Two terminals Vct1 and Vramp are provided to control the operation of an amplifier embodied in the circuit. Vramp provides switching on or off the amplifier, and Vct1 in the presence of an applied voltage provides various levels of amplification in dependence upon the applied voltage value. Therefore, when it is provided with a voltage the amplifier is switched on to a level determined by the voltage value of Vct1. Conversely, when Vramp is switched off, the value of Vct1 does not affect the amplifier, which is switched off.

A voltage control (Vct1) converter circuit 30 serves to convert input control voltage Vct1 which has a variable value of between 0V and 3.3V into a current coupled to bias block generators 32a and 32b which bias the base of each of the transistors 20a and 20b respectively. Thus, a current proportional to the voltage signal Vct1 is provided to bias the base of the two transistors 20a and 20b.

Blocks 34a and 34b each consist of a high value bleed resistor having a value of over 1 or 2 KΩ and preferably greater than about 5 KΩ. Adjacent to and coupled with each of the bleed resistors Rbleed#1 and Rbleed#2 are positive metal-oxide-semiconductor (PMOS) transistors. When the PMOS transistors are in an OFF state, the associated bleed resistors partially bypass the PMOS transistors to improve the linearity of the power control profile of the amplifier.

Shunt circuit blocks 36a and 36b are coupled to a DC voltage source and the base of the transistors 20a and 20b respectively. Shunt circuit block 36 consists of a capacitor coupled in series with a PMOS transistor. Operationally the shunt block 36 redirects an RF signal present at an IN terminal to an analog ground terminal VCC0 in order to prevent the power amplifier from operating in a Class B mode of operation. This extends the dynamic range of the power control while maintaining the nominal power level at the IN terminal. It is preferred that the metal-oxide-semiconductor (MOS) gate within the shunt block have a substantially low resistance when the switch is ON such that it shunts AC signals at the base of the transistor as intended. Notwithstanding, it is preferred that the MOS gate have a low leakage ability and thus a suitably high resistance when the gate is switched off preventing AC signals from being shunted. Thus, for example, the resistance of the gate when it is switched on should be less than 20 Ω and preferably less than 5 Ω, and when the gate is switched off the resistance should be greater than 100 Ω, and preferably greater than 200 Ω.

Conveniently the PMOS gate within the shunt block 36 connected to a positive voltage supply VCC0 is used to provide an active-high shunt block; thus when Vct1 is high, and has a positive voltage applied, thus the output power is high, the shunt blocks 36a and 36b are in an OFF state. Of course, inverted logic and voltages could be used in an alterative embodiment. The capacitor in series with the PMOS gate within blocks 36a and 36b prevents DC current from flowing through the PMOS gate. The advantages of this shunt circuit are significant. The provision of fast MOS and bipolar junction transistors (BJT) is most practicable using silicon germanium technology.

The amplifier described heretofore controlled in part by an applied control voltage applied to a terminal Vct1 and having an improved performance in view of the Shunt attenuator circuits 36a, 36b and the bleed resistor blocks 34a and 34b is also controlled by a master digital switch 38 having a terminal Vramp which allows the amplifier to be switched ON or OFF in a binary fashion, regardless of the voltage applied at the Vct1 terminal, as opposed to conventional prior art circuits where a switch is disposed at the collector of the power transistors

In summary, the circuit shown in FIG. 25 has various significant advantages over prior art amplifying circuits for use in battery-powered telephony. Due to the variable control of the amplifier's output response being coupled to and dependent upon the provision of current to the base of the amplifying transistors rather than the collector, power conservation is afforded. The provision of two switches in series, wherein a master digital switch 38 is serially connected to a variable switch operated by a voltage at Vct1 provides the ability to switch on and off the amplifier without regard to the voltage level at Vct1; this also allows resumption of the voltage level at Vct1 when the digital switch is switched ON. This is particularly advantageous when transmission is in bursts and the amplifier is being rapidly switched ON and OFF. Furthermore, bleed resistors 34a and 34b provide a more linear power control profile. Yet still further, shunt circuits coupled to the base of the amplifying transistors prevent the amplifier from operating in unwanted modes of operation. Providing this topology of fast switching BJT and CMOS gates is manufactureable and is practicable with SiGe technology described above.

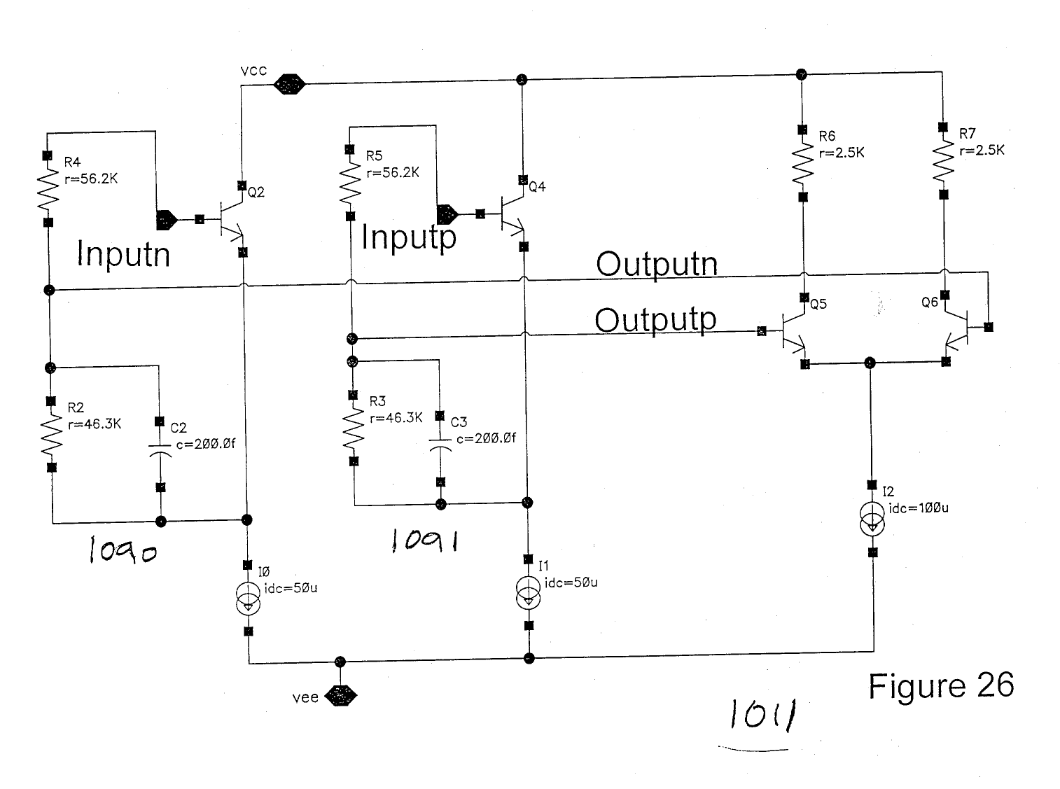

The methods for producing SiGe based semiconductor devices as described above are for example utilized in manufacturing a voltage level shifting circuit. Referring now to FIG. 26, illustrated is a dual level shifter circuit 1011 that is possibly used with a current mode logic (CML) circuit. The dual level shifter circuit 1011 comprises a first and a second input terminal, and a first and a second transistor Q2 and Q4 each having a collector, a base and an emitter. The collectors of the two transistors Q2 and Q4 are coupled to a common voltage terminal, the base of the first and second transistors are coupled to the first and second input terminal respectively; and the base of each of the first and second transistor is coupled to a voltage divider circuit 1090 and 1091. Each voltage divider circuit 1090 and 1091 comprises a first R2, R4 and a second R3, R5 resistor in series between the respective base and emitter of respective transistors, and a node between each first and second resistor in series, the node being an output node. The voltage level shifting circuit 1011 further comprises a differential pair of transistors Q5 and Q6 and two load circuits comprising a resistive circuit element in parallel with a circuit element for conducting current without affecting a voltage drop there across in a substantial manner, each load circuit coupled to a collector of the differential pair for providing a substantially constant voltage less than a circuit supply voltage at the respective collectors in operation, wherein each voltage divider has a capacitor connected in parallel with one of the first and second series resistors. The dual level shifter obviates much of the prior art problems induced by effects of an unwanted low-pass filter formed by an RC circuit consisting of a resistor, and the parasitic capacitance at the input of a transistor in the following stage. By the addition of capacitors C2 and C3, each having a value of 200ƒF, across resistors R2 and R3 respectively, each having a resistance of 46.3KΩ, effectively providing an alternative path for high frequency AC, a high-pass filter is formed which offsets the limitations of the unwanted low-pass filter. By providing the capacitor C2 in parallel with resistor R3, the emitter rather than the base of transistor Q4 is loaded, which is preferable since the impedance of the emitter is lower than that of the base.

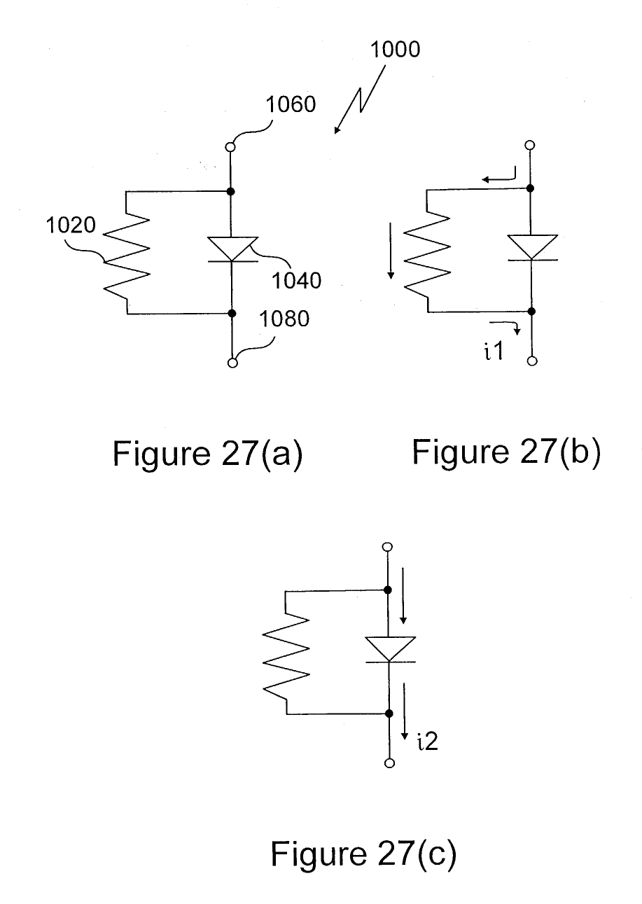

Referring now to FIG. 27 shown is a load circuit 1000 for provision of a direct current to a voltage level shifting circuit. The load circuit 1000 comprises a load resistor 1020 and a diode 1040 in the form of a Schottky diode disposed in parallel between the power supply and a powered circuit. Input port 1060 of the load circuit is connected to a DC power supply such as a battery for providing a current from the battery to the circuit. Output port 1080 is electrically coupled to an input of the powered circuit in the form of a high-speed battery powered circuit for propagation of the current to the circuit.

The load circuit 1000 and the level shifter circuit 1011 are preferably used in combination. Both the voltage level shifting circuit 1011 as well as the load circuit 1000 are manufactureable and are practicable with SiGe technology described above.

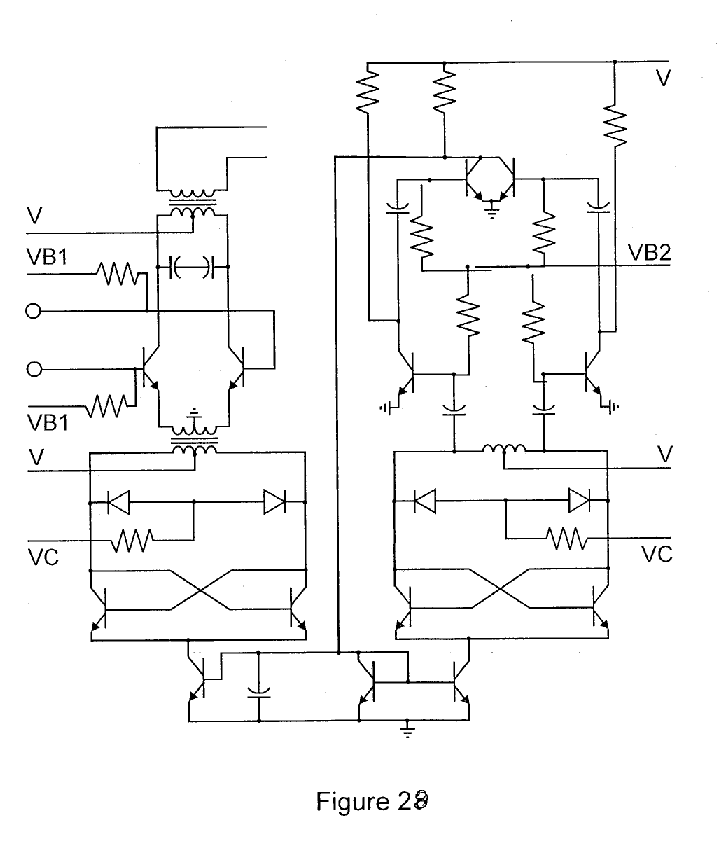

The methods for producing SiGe based semiconductor devices as described above are also utilized in the manufacturing of an active impedance notch filter circuit for use with a radio frequency (RF) amplifier. One example of an active impedance notch filter circuit coupled with an RF amplifier, and envisaged as being a design convenient for integrated circuit manufacture, is shown in FIG. 28. A pair of transistors 12 and 14 provides an RF amplifier. Collector electrodes of the transistors 12 and 14 are connected across a primary winding 16 of an output transformer 15. Emitter electrodes of the transistors 12 and 14 are connected across a center taped winding 27 of a coupling transformer 25. Base electrodes of the transistors 12 and 14 are connected to be differentially driven by an RF signal, when such is applied across a pair of input terminals 10. The base electrodes of the transistors 12 and 14 are coupled with a source of voltage bias VB1 via resistors 11 and 13 respectively, as shown. The output transformer 15 includes a secondary winding 17, connected to output leads 19, for providing an amplified RF signal to on-following radio receiver circuitry, not shown. Capacitors 18 are connected across the primary winding 16 to enhance the amplification of RF signals in a frequency band of interest. Energizing current is supplied from a voltage supply V, via a center tap of the primary winding 16 and ground connected at the center tap of the winding 27. The transistors 12 and 14 are biased, via the resistors 11 and 13, into a linear area of operation such that RF signals applied differentially across the input terminals 10 are amplified with an amplifying gain and appear across the output leads 19. Although the frequency of an image signal is usually remote from the frequency band of interest, such signals can be amplified to appear at the output leads 19 with substantial signal energy, unless intercepted or rejected by a filter, for example, a notch filter as illustrated in FIG. 28.

The notch filter is provided by first and second oscillator circuits with gain controlled by slave and master biasing circuits in response to functioning of the second oscillator circuit as sensed by a sensing circuit. The first oscillator circuit is provided by circuit components labeled 21-26, 28 and 29. Transistors 22 and 24 are cross-coupled as shown via leads 21 and 23 in a bistable circuit configuration with collector electrodes connected across an inductive winding 26 of the coupling transformer 25. Emitter electrodes of the transistors 22 and 24 are connected in common with a collector electrode of a transistor 65. A pair of capacitance diodes 28, also known as varactor diodes, are connected in series opposition, as shown, across the winding 26 to provide a tank circuit which is tunable by a control voltage source VC applied via a resistor 29. Operating current is supplied from the voltage supply V via a center tap of the inductive winding 26 and via a grounded emitter of the transistor 65. The transistor 65 is configured to operate as a current following or slave circuit, sometimes referred to as a current mirror, for limiting a flow of the operating current and thereby control the gain of the first oscillator circuit. The control of the gain of the first oscillator circuit is essential for optimal attenuation of any signal of a predetermined undesired frequency, for example the image frequency signal. Ideally the first oscillator is operated with sufficient gain to be in a marginally oscillatory state if it were not loaded by being coupled with the RF amplifier. When the first oscillator is coupled to the RF amplifier, loading quenches the marginal oscillations and thus achieves a desired marginally quiescent state of operation. However without oscillatory operation a problem arises in that there is no convenient reference for gain regulation. This problem is overcome by providing the second oscillator circuit, which is similar to the first oscillator circuit and is used as a reference for gain regulation.

The second oscillator circuit is provided by circuit components labeled 31-34, 36, 38 and 39 and as can be seen with reference to FIG. 28, the second oscillator is of similar structure as compared to the first oscillator circuit. Transistors 32 and 34 are cross-coupled via leads 31 and 33 in a bistable circuit configuration with collector electrodes connected across an inductive winding 36. Emitter electrodes of the transistors 32 and 34 are connected in common with the collector electrode of a transistor 62. A pair of varactor diodes 38, connected across the inductive winding 36, provides a tank circuit which is tunable by the control voltage source VC via a resistor 39. Operating current is supplied from the voltage supply V, via a center tap of the inductive winding 36 and via a grounded emitter electrode of the transistor 62, configured to operate as a current mirror.

A bias control circuit for controlling the gains of the first and second oscillator circuits is provided by circuit components labeled 41-44, 46, and 48. Transistors 42 and 44 have emitter electrodes connected to ground and collector electrodes coupled to the voltage supply V via a resistor 61. The base electrodes of the transistors 42 and 44 are connected to a source of bias voltage VB2 by resistors 41 and 43 and are coupled by capacitors 46 and 48 to junctions 45 and 47. In one example of less complexity than the example shown in FIG. 28, the junctions 45 and 47 are directly connected across the inductive winding 36 at junctions 35 and 37 respectively. However, in the illustrated example an additional stage of amplification is provided by circuit components 51-56, 58 and 59. This additional stage of amplification improves the velocity and precision with which optimal operating gain control is achieved. In the additional stage of amplification transistors 52 and 54 have emitter electrodes connected to ground and collector electrodes coupled to the voltage supply V, via resistors 55 and 59. The base electrodes of the transistors 52 and 54 are connected to the source of bias voltage VB2, by resistors 51 and 53, and are coupled by capacitors 56 and 58 to the inductive winding 36, via the junctions 35 and 37 respectively. A transistor 60 is connected in a current source configuration, as shown, with the resistor 61 and ground to provide a master bias control circuit and a capacitor 63 is connected between the resistor 61 and ground.

At a moment when power is applied across the power terminals V and ground, initially the oscillator circuits are inactive. Current conduction through the transistor 60 rises until the voltage drop establishes a limit across the resistor 61 and the base emitter junction drop across the transistor 60. Current conductions through the transistors 62 and 65 mimic current conduction through the transistor 60. The value of the resistor 61 is chosen to provide sufficient current to initiate oscillatory operation in the second oscillator circuit. If the second oscillator circuit were in a quiescent state, that is not oscillating, the transistors 52 and 54 as well as the transistors 42 and 44 are biased to be non-conductive by the source of bias voltage VB2. When the second oscillator circuit is oscillating, as it usually is, the positive peaks of the oscillatory signal cause the transistors 52 and 54 to alternately conduct and consequently transistors 42 and 44 alternately conduct even more vigorously. Conduction by the transistors 42 and 44 increases the voltage drop across the resistor 61 and consequently reduces the flow of operating current for the second oscillator circuit via the transistor 62. The second oscillator settles into a current starved mode of operation such that current conductions by the transistor pair 32 and 34 are mutually exclusive occurrences resembling that of a class C amplifier operation. The transistor 65 provides a slave bias circuit which mimics or mirrors current conduction via the transistors 60 and 62. Hence the first oscillator likewise settles into a current starved mode of operation, however as its tank circuit is loaded by coupling to the RF amplifier its initial oscillations, if any, are quenched. Accordingly the first oscillator assumes a marginally quiescent state of operation.

Hence a narrow stop band or notch filter function is achieved. RF input signals in a band of interest appear on the output leads 19 being amplified with a first gain. As the tank circuit in the first oscillator circuit is tuned to the image frequency. Each half of the winding 27 of a coupling transformer 25 provides an impedance in series with each of the emitter electrodes of the transistors 12 and 14. The impedance is sharply increased for signals near the frequency of the notch so that little, ideally none, of the image frequency signal traverses the RF amplifier.

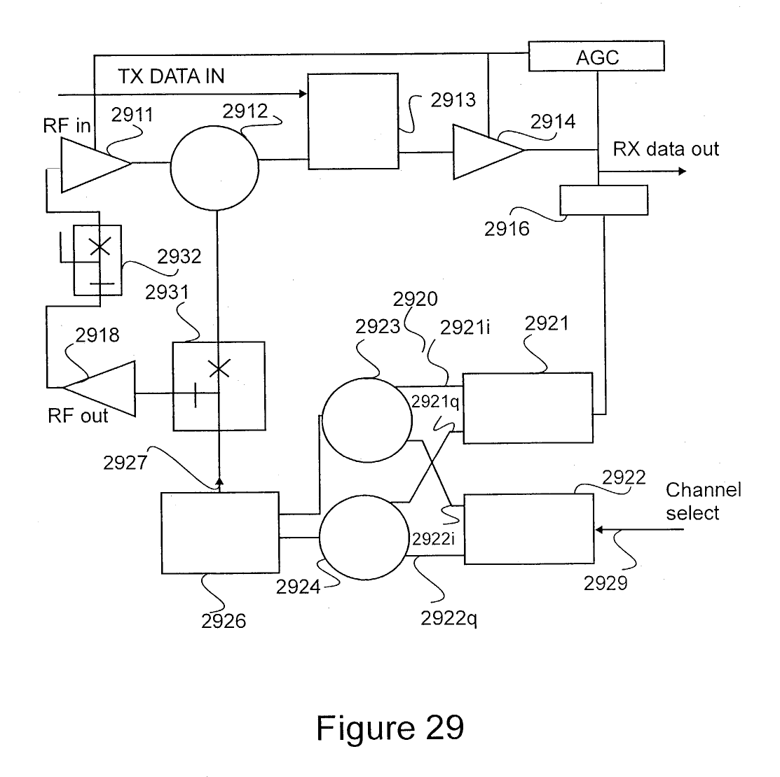

The methods for producing SiGe based semiconductor devices as described above are further used in manufacturing of radio transceivers wherein some of the components are used in common for both the reception and the transmission of frequency modulated (FM) radio signals. In FIG. 29, such a FM transceiver is shown. The FM transceiver includes a radio frequency (RF) amplifier 2911, preferably of a type referred to as a low noise amplifier, having an input coupled to an antenna 2906, for amplifying radio signals received by the antenna 2906. The RF amplifier 2911 has an output port connected to a mixer 2912 and a gain control port for receiving a control voltage from an automatic gain control (AGC) circuit 2915. The mixer 2912 is preferably a balanced mixer, which in integrated circuit technology may be conveniently provided by a Gilbert cell. The mixer 2912 operates to produce sum and difference signals by mixing the amplified radio signals with a local oscillator signal from a local oscillator 2920, in a well-known manner. The sum and difference signals are supplied to a low-pass filter 2913, which is designed to have a bandwidth of a maximum frequency substantially corresponding to a maximum deviation of frequency of any radio signal intended for reception. Accordingly only those radio signals received are passed by the low-pass filter 2913, which have a carrier or center frequency being close to the frequency of the local oscillator signal. In other words the architecture as thus far described provides a so-called zero hertz IF receiver, sometimes referred to as a direct conversion receiver. The output of the low-pass filter 2913 is amplified by an amplifier 2914 and coupled to a received (RX) data output 2909, as well as with an input of the AGC circuit 2915. Similar to the amplifier 2911, the amplifier 2914 includes a gain control input so that the AGC circuit 2915 controls the gain of the amplifier 2914. The signals from the low-pass filter 2913 may also be referred to as baseband signals and the amplifier 2914 may be referred to as a base band amplifier.

The local oscillator 2920 includes a channel selector, in this example a frequency synthesizer 2922. A frequency synthesizer 2922 is directed by a selection device, not shown, via a channel select input 2929, to provide alternating current signals of a selected predefined frequency in quadrature relationship at outputs labeled 2922i and 2922q. A voltage-controlled oscillator (VCO) 2916 provides an alternating current signal for adjusting the frequency of the local oscillator signal. In one example the VCO 2916 is a low frequency ring oscillator, which generates the alternating current signal with a frequency being inversely related to a DC potential from the output of the amplifier 2914. A phase shift circuit 2921 provides half frequency replicas of the alternating current signal in quadrature relationship at outputs labeled 2921i and 2921q. A balanced mixer 2923 is coupled to mix the signals from the outputs 2921i and 2922i to produce mixed signals. A balanced mixer 2924 is coupled to mix the signals from the outputs 2921q and 2922q to produce mixed signals. The mixed signal products from the balanced mixers 2923 and 2924 are utilized in an adder limiter circuit 2926, which up converts the mixed signal products by performing a continuous addition function to the produce the required local oscillator signal at an output 2927.

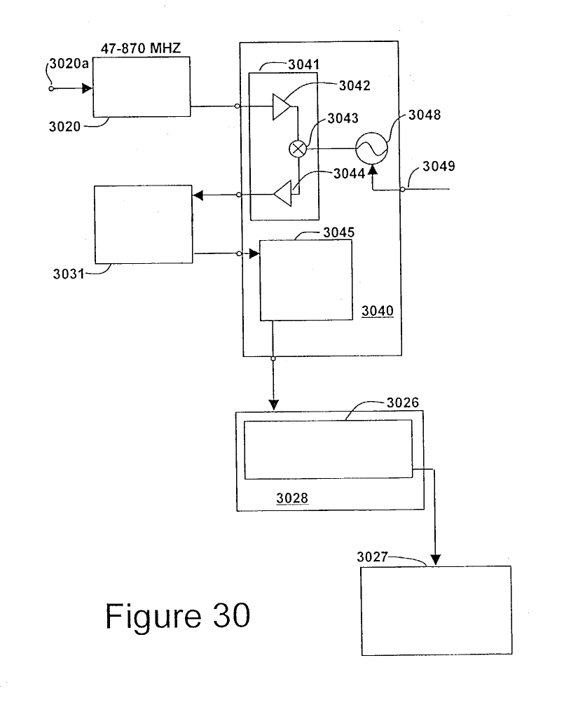

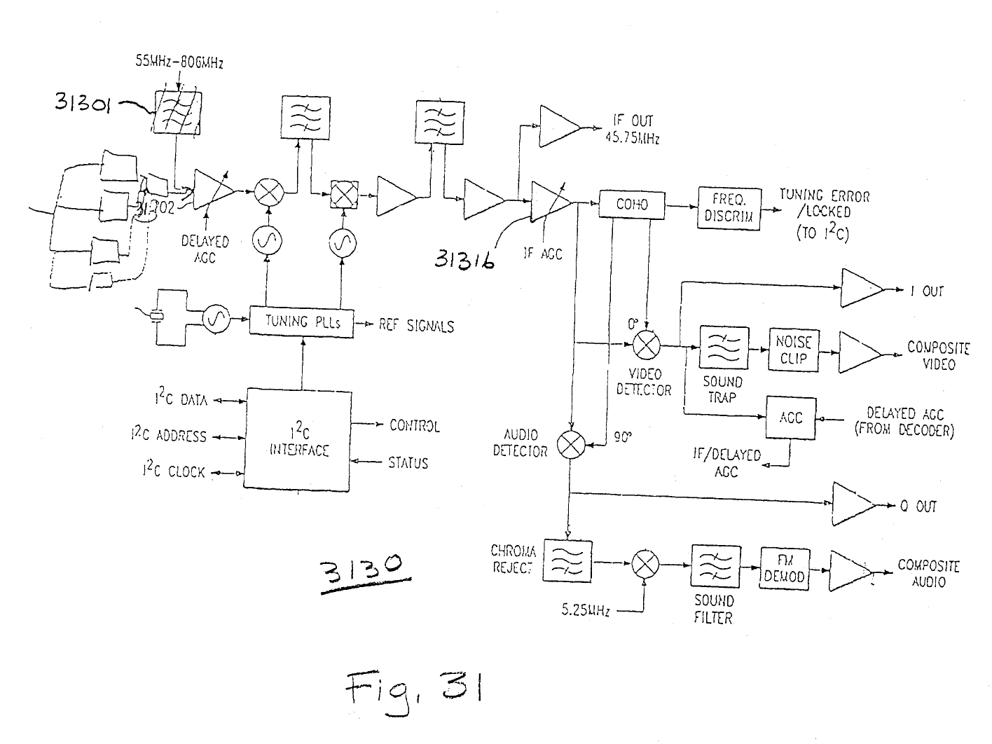

The methods for producing SiGe based semiconductor devices as described above are further used in manufacturing tunable receivers for selecting and receiving television signals and the like. Referring to FIG. 30, a television receiver includes a tuner chip 3040 for supplying digital representations of a TV signal to a microcomputer chip 3028, which includes a TV processor 3026 for processing the TV signal preparatory to visible and audible presentation, via TV display and sound elements 3027. The microcomputer chip 3028 consists solely of digital circuit elements.

The tuner chip 3040 is an integrated circuit manufacturable in accordance with methods of the instant invention. External connections and/or beam lead connections with elements in the tuner chip are expensive and by design are minimized. Each of the illustrated external or beam lead connection with the tuner chip 3040 is indicated in the drawings by a hollow dot. The tuner chip 3040 includes a frequency conversion circuit 3041, an analog to digital (A/D) converter circuit 3045 and a local oscillator 3048. The frequency conversion circuit 3041 basically includes a low noise amplifier (LNA) 3042, a mixer 3043 and a buffer amplifier 3044. In this example it is preferred that the mixer 3031 be a balanced mixer.

In operation, any signals passed from an input terminal 3020a, via a band-pass filter 3020, are amplified by the LNA 3042 and applied to a terminal of the mixer 3043. Automatic gain control circuitry, not shown, may be used to regulate the amplification of the LNA 3042 so that it will not be overdriven in the presence of strong signals at the input terminal 3020a. The local oscillator 3048 is responsive to a control signal, on a lead 3049, for supplying a local oscillator signal, to the mixer 3043, at a selected frequency. A mixed signal from the output of the mixer 3043 is transferred, by the buffer amplifier 3044, to a 6 MHz bandwidth-pass filter 3031, which attenuates signals outside of a 6 MHz channel. Any signals with frequencies within the pass band are transmitted to the A/D converter circuit 3045. The A/D converter circuit 3045 provides encoded digitized samples of the passed signals at a rate of at least twice that of the highest frequency required to be passed by the pass filter 3031. The encoded digitized samples are passed from the tuner chip 3040 to the microcomputer chip 3028, which prepares signals for operation of the TV display and sound elements 3027, based on information having been encoded in the digitized samples.

Referring now to FIG. 31, a broadband television tuner is shown in block diagram. RF signals are received in tuner 3130 through input filter 31301. Input filter 31301 is a switchably selectable filter to pass a selected range within the frequency range across the television frequency band. In this fashion, the switchably selectable filter 31301 passes any one selected channel through careful switching. That said, unlike the above described large bandwidth filter a narrower bandwidth filter is used. The selected range is typically a range about a selected channel and is of sufficient size to provide good linearity across the channel. For example, each range covers 70 MHz of bandwidth with 20 MHz of overlap to ensure that each channel is somewhat central within a range. In a preferred embodiment, a simple switching network directs the signals through one of a plurality of filters, each filter passing a predetermined range corresponding to a channel, based on the selected channel. Of course, a tunable filter is also useful with the present embodiment. Filter 31301 operates to attenuate signals above an input cutoff frequency corresponding to a frequency in the television band above the selected channel frequency. Similar to prior art non-integrated tuners, filter 31301 is a filter that attenuates most television channels from the received signal.

Following filter 31301, the RF signal passes through delayed automatic gain control (AGC) amplifier 31302, which operates in conjunction with AGC amplifier 31316 to control the overall signal level in tuner 3130. Amplifier 31302 is a variable gain amplifier or a variable gain attenuator in series with a fixed gain amplifier. The preferred embodiment of amplifier 31302 comprises a low noise amplifier (LNA) with a high linearity that is sufficient to pass the entire television band. Alternatively, each of the plurality of filters comprises a LNA for amplifying the associated frequency band.

The methods for producing SiGe based semiconductor devices as described above are further used in manufacturing opto-electronic devices. The seed-layer concept of the instant invention advantageously facilitates the construction of such devices. Opto-electronic devices include for example photodetectors, including P-I-N type as well as Avalanche type photodetectors. Here, the light sensitive layer is a layer of Si/SiGe. Furthermore, waveguide devices are optionally manufactured according to methods of the instant invention. A waveguide is constructed using the difference in the index of refraction between a Si-layer and various SiGe-layers with different fractions of Ge. Also optical emitters are possibly constructed according to methods of the instant invention, wherein a Si/SiGe hetero-structure conducive to the emission of light is grown on bulk silicon.

The above described elementary semiconductor devices and semiconductor building blocks are all manufactured according to a method of the instant invention. That said, it is noted that the present invention is not restricted to the elementary semiconductor devices and semiconductor building blocks as described vide infra, but equally applies to manufacturing other elementary semiconductor devices and semiconductor biding blocks. Readers of the foregoing disclosure will envisage various other embodiments within the spirit and scope of the present invention, the breadth of which is of record in the appended claims.

What is claimed is:

1. A method of applying a semiconductor seed layer to a substrate having regions of exposed semiconductor material and regions of exposed dielectric material, comprising the step of:
disposing the substrate in a growth chamber and nucleating the seed layer by exposing the semiconductor material and dielectric material to an atmosphere of gases presented at a predetermined flow rate, temperature and pressure selected to provide contiguous growth of the seed layer, the seed layer growing in a single crystal lattice over predetermined windows within the mixed topology substrate.

2. A method as defined in claim 1, wherein the applied semiconductor seed layer and the substrate having regions of exposed semiconductor material and regions of exposed dielectric material form a semiconductor structure.

3. A method according to claim 2, wherein the semiconductor structure comprises at least an elementary semiconductor device.

4. A method according to claim 3, wherein the at least an elementary semiconductor device comprises a bipolar transistor.

5. A method according to claim 3, wherein the at least an elementary semiconductor device comprises a field-effect transistor.

6. A method according to claim 5, wherein the field-effect transistor is a metal-oxide-semiconductor field-effect transistor.

7. A method according to claim 5, wherein the field-effect transistor is a junction field-effect transistor.

8. A method according to claim 3, wherein the at least an elementary semiconductor device comprises a capacitor.

9. A method according to claim 3, wherein the at least an elementary semiconductor device comprises a resistor.

10. A method according to claim 3, wherein the at least an elementary semiconductor device comprises an inductor.

11. A method according to claim 3, wherein the at least an elementary semiconductor device comprises a transformer.

12. A method according to claim 3, wherein the at least an elementary semiconductor device comprises a diode.

13. A method according to claim 12, wherein the diode is a varactor diode.

14. A method according to claim 2, wherein the semiconductor structure comprises two or more elementary semiconductor devices, the elementary semiconductor devices forming semiconductor building blocks.

15. A method according to claim 14, wherein a semiconductor building block comprises an amplifier.

16. A method according to claim 15, wherein the amplifier is a buffer amplifier.

17. A method according to claim 15, wherein the amplifier is a low noise amplifier.

18. A method according to claim 15, wherein the amplifier is an automatic gain control amplifier.

19. A method according to claim 15, wherein the amplifier is a variable gain amplifier.

20. A method according to claim 14, wherein a semiconductor building block comprises an adder.

21. A method according to claim 14, wherein a semiconductor building block comprises a mixer.

22. A method according to claim 21, wherein the mixer is a balanced mixer.

23. A method according to claim 14, wherein a semiconductor building block comprises a filter.

24. A method according to claim 23, wherein the filter is a low-pass filter.

25. A method according to claim 23, wherein the filter is a band-pass filter.

26. A method according to claim 23, wherein the filter is a switchably selectable filter.

27. A method according to claim 23, wherein the filter is a tunable filter.

28. A method according to claim 14, wherein a semiconductor building block comprises a frequency synthesizer.

29. A method according to claim 14, wherein a semiconductor building block comprises a frequency conversion circuit.

30. A method according to claim 14, wherein a semiconductor building block comprises a tank circuit.

31. A method according to claim 14, wherein a semiconductor building block comprises a voltage control circuit.

32. A method according to claim 14, wherein a semiconductor building block comprises a voltage divider circuit.

33. A method according to claim 14, wherein a semiconductor building block comprises an analog to digital converter circuit,

34. A method according to claim 14, wherein a semiconductor building block comprises an oscillator.

35. A method according to claim 34, wherein the oscillator is a voltage-controlled oscillator.

36. A method according to claim 35,wherein the voltage-controlled oscillator is a low frequency ring oscillator.

37. A method according to claim 14, wherein a semiconductor building block comprises a bias control circuit.

38. A method according to claim 14, wherein a semiconductor building block comprises an automatic gain control circuit.

39. A method according to claim 2, wherein the semiconductor structure comprises an opto-electronic device.

40. A method according to claim 39, wherein the opto-electronic device comprises a photodetector.

41. A method according to claim 40, wherein the photodetector is a P-I-N type photodetector.

42. A method according to claim 40, wherein the photodetector is an Avalanche type photodetector.

43. A method according to claim 39, wherein the opto-electronic devices comprises a waveguide.

44. A method according to claim 39, wherein he opto-electronic devices comprises an optical emitter.

45. A method of applying a semiconductor seed layer, the seed layer essentially consisting of a silicon layer containing impurities, to a mixed topology substrate having regions of exposed semiconductor material and regions of exposed dielectric material, the method comprising the step of:
disposing the substrate in a growth chamber and nucleating the seed layer by exposing the semiconductor material and dielectric material to an atmosphere of gases presented at a predetermined flow rate, temperature and pressure selected to provide contiguous growth of the seed layer, the seed layer growing in a single crystal lattice over predetermined windows within the mixed topology substrate.

46. A method according to claim 45, wherein the dielectric material is an SiₓO_{y}N_{z} material.

47. A method according to claim 45, wherein the semiconductor structure comprises at least an elementary semiconductor device.

48. A method according to claim 47, wherein the at least an elementary semiconductor device comprises a bipolar transistor.

49. A method according to claim 47, wherein the at least an elementary semiconductor device comprises a field-effect transistor.

50. A method according to claim 49, wherein the field-effect transistor is a metal-oxide-semiconductor field-effect transistor.

51. A method according to claim 49, wherein the field-effect transistor is a junction field-effect transistor.

52. A method according to claim 47, wherein the at least an elementary semiconductor device comprises a capacitor.

53. A method according to claim 47, wherein the at least an elementary semiconductor device comprises a resistor.

54. A method according to claim 47, wherein the at least an elementary semiconductor device comprises an inductor.

55. A method according to claim 47, wherein the at least an elementary semiconductor device comprises a transformer.

56. A method according to claim 47, wherein the at least an elementary semiconductor device comprises a diode.

57. A method according to claim 56, wherein the diode is a varactor diode.

58. A method according to claim 45, wherein the semiconductor structure comprises two or more elementary semiconductor devices, the elementary semiconductor devices forming semiconductor building blocks.

59. A method according to claim 58, wherein a semiconductor building block comprises an amplifier.

60. A method according to claim 59, wherein the amplifier is a buffer amplifier.

61. A method according to claim 59, wherein the amplifier is a low noise amplifier.

62. A method according to claim 59, wherein the amplifier is an automatic gain control amplifier.

63. A method according to claim 59, wherein the amplifier is a variable gain amplifier.

64. A method according to claim 58, wherein a semiconductor building block comprises an adder.

65. A method according to claim 58, wherein a semiconductor building block comprises a mixer.

66. A method according to claim 65, wherein the mixer is a balanced mixer.

67. A method according to claim 58, wherein a semiconductor building block comprises a filter.

68. A method according to claim 67, wherein the filter is a low-pass filter.

69. A method according to claim 67, wherein the filter is a band-pass filter.

70. A method according to claim 67, wherein the filter is a switchably selectable filter.

71. A method according to claim 70, wherein the filter is a tunable filter.

72. A method according to claim 58, wherein a semiconductor building block comprises a frequency synthesizer.

73. A method according to claim 58, wherein a semiconductor building block comprises a frequency conversion circuit.

74. A method according to claim 58, wherein a semiconductor building block comprises a tank circuit.

75. A method according to claim 58, wherein a semiconductor building block comprises a voltage control circuit.

76. A method according to claim 58, wherein a semiconductor building block comprises a voltage divider circuit.

77. A method according to claim 58, wherein a semiconductor building block comprises an analog to digital converter circuit,

78. A method according to claim 58, wherein a semiconductor building block comprises an oscillator.

79. A method according to claim 78, wherein the oscillator is a voltage-controlled oscillator.

80. A method according to claim 79,wherein the voltage-controlled oscillator is a low frequency ring oscillator.

81. A method according to claim 58, wherein a semiconductor building block comprises a bias control circuit.

82. A method according to claim 58, wherein a semiconductor building block comprises an automatic gain control circuit.

83. A method according to claim 45, wherein the semiconductor structure comprises an opto-electronic device.

84. A method according to claim 83, wherein the opto-electronic device comprises a photodetector.

85. A method according to claim 84, wherein the photodetector is a P-I-N type photodetector.

86. A method according to claim 84, wherein the photodetector is an Avalanche type photodetector.

87. A method according to claim 83, wherein the opto-electronic device comprises a waveguide.

88. A method according to claim 83, wherein he opto-electronic devices comprise an optical emitter.

89. A semiconductor device comprising:
a silicon layer of a first conductivity type;
a layer of SiGe of a second conductivity type covering at least a region of the silicon layer;
a first layer of polysilicon of the second conductivity type at least substantially supported by and covering a portion of the SiGe layer; and,
an electronic component formed within the semiconductor device.

90. A semiconductor device according to claim 89, wherein the first layer of polysilicon covering a substantial portion of the SiGe layer with the exception of a small window;
and comprising a second layer of polysilicon of the first conductivity type covering the window and contacting the SiGe layer; and wherein the silicon layer of a first conductivity type and the layer of SiGe of a second conductivity type are in a contiguous relationship with a same nucleated seed layer.

91. A semiconductor device according to claim 89, wherein the semiconductor device comprises at least an elementary semiconductor device.

92. A semiconductor device according to claim 91, wherein the at least an elementary semiconductor device comprises a bipolar transistor.

93. A semiconductor device according to claim 91, wherein the at least an elementary semiconductor device comprises a field-effect transistor.

94. A semiconductor device according to claim 93, wherein the field-effect transistor is a metal-oxide- semiconductor field-effect transistor.

95. A semiconductor device according to claim 93, wherein the field-effect transistor is a junction field-effect transistor.

96. A semiconductor device according to claim 91, wherein the at least an elementary semiconductor device comprises a capacitor.

97. A semiconductor device according to claim 91, wherein the at least an elementary semiconductor device comprises a resistor.

98. A semiconductor device according to claim 91, wherein the at least an elementary semiconductor device comprises an inductor.

99. A semiconductor device according to claim 91, wherein the at least an elementary semiconductor device comprises a transformer.

100. A semiconductor device according to claim 91, wherein the at least an elementary semiconductor device comprises a diode.

101. A semiconductor device according to claim 100, wherein the diode is a varactor diode.

102. A semiconductor device according to claim 89, wherein the semiconductor device comprises two or more elementary semiconductor devices, the elementary semiconductor devices forming semiconductor building blocks.

103. A semiconductor device according to claim 102, wherein a semiconductor building block comprises an amplifier.

104. A semiconductor device according to claim 103, wherein the amplifier is a buffer amplifier.

105. A semiconductor device according to claim 103, wherein the amplifier is a low noise amplifier.

106. A semiconductor device according to claim 103, wherein the amplifier is an automatic gain control amplifier.

107. A semiconductor device according to claim 103, wherein the amplifier is a variable gain amplifier.

108. A semiconductor device according to claim 102, wherein a semiconductor building block comprises an adder.

109. A semiconductor device according to claim 102, wherein a semiconductor building block comprises a mixer.

110. A semiconductor device according to claim 109, wherein the mixer is a balanced mixer.

111. A semiconductor device according to claim 102, wherein a semiconductor building block comprises a filter.

112. A semiconductor device according to claim 111, wherein the filter is a low-pass filter.

113. A semiconductor device according to claim 111, wherein the filter is a band-pass filter.

114. A semiconductor device according to claim 111, wherein the filter is a switchably selectable filter.

115. A semiconductor device according to claim 11 1, wherein the filter is a tunable filter.

116. A semiconductor device according to claim 102, wherein a semiconductor building block comprises a frequency synthesizer.

117. A semiconductor device according to claim 102, wherein a semiconductor building block comprises a frequency conversion circuit.

118. A semiconductor device according to claim 102, wherein a semiconductor building block comprises a tank circuit.

119. A semiconductor device according to claim 102, wherein a semiconductor building block comprises a voltage control circuit.

120. A semiconductor device according to claim 102, wherein a semiconductor building block comprises a voltage divider circuit.

121. A semiconductor device according to claim 102, wherein a semiconductor building block comprises an analog to digital converter circuit,

122. A semiconductor device according to claim 102, wherein a semiconductor building block comprises an oscillator.

123. A semiconductor device according to claim 122, wherein the oscillator is a voltage-controlled oscillator.

124. A semiconductor device according to claim 123, wherein the voltage-controlled oscillator is a low frequency ring oscillator.

125. A semiconductor device according to claim 102, wherein a semiconductor building block comprises a bias control circuit.

126. A semiconductor device according to claim 102, wherein a semiconductor building block comprises an automatic gain control circuit.

127. A semiconductor device according to claim 89, wherein the semiconductor structure comprises an opto-electronic device.

128. A semiconductor device according to claim 127, wherein the opto-electronic device comprises a photodetector.

129. A semiconductor device according to claim 128, wherein the photodetector is a P-I-N type photodetector.

130. A semiconductor device according to claim 128, wherein the photodetector is an Avalanche type photodetector.

131. A semiconductor device according to claim 127, wherein the opto-electronic device comprises a waveguide.

132. A semiconductor device according to claim 127, wherein the opto-electronic device comprises an optical emitter.
